(19) United States
(12) Patent Application Publication
(10) Pub. No.: US 2015/0228817 A1
(43) Pub. Date: Aug. 13, 2015

(54) SOLAR CELL

(71) Applicant: Panasonic Intellectual Property Management Co., Ltd., Osaka (JP)

(72) Inventors: Hirotada INOUE, Hyogo (JP); Kazunori FUJITA, Gifu (JP); Yasuko HIRAYAMA, Osaka (JP)

(21) Appl. No.: 14/695,670

(22) Filed: Apr. 24, 2015

Related U.S. Application Data
(63) Continuation of application No. PCT/JP2013/006797, filed on Nov. 19, 2013.

(30) Foreign Application Priority Data
Nov. 29, 2012 (JP) 2012-260876

(51) Int. Cl. H01L 31/0236

(52) U.S. Cl. CPC H01L 31/02366

(57) ABSTRACT

A solar cell has a plurality of texture elements adjacent to each other, wherein the texture elements include a first texture element having a vertex, the curvature radius of which is larger than the curvature radius of the valley between adjacent texture elements.

### CROSS REFERENCE TO RELATED APPLICATIONS

This application is a continuation under 35 U.S.C. §120 of PCT/JP2013/006797, filed Nov. 19, 2013, which is incorporated herein by reference and which claimed priority under 35 U.S.C. §119 to Japanese Application No. 2012-260876, filed Nov. 29, 2012, the entire content of which is also incorporated herein by reference, and 35 U.S.C. §119 priority is also claimed hereto.

### TECHNICAL FIELD

The present invention generally relates to a solar cell.

### BACKGROUND ART

There has been known a technology in which texture elements having unevenness from several μm to several tens μm are provided on the light-receiving face of a solar cell for the purpose of enhancing power generation efficiency in the solar cell. By providing texture elements, the reflection of light incident on the light-receiving face from outside can be reduced, and the effect of optical confinement to the inside of the solar cell can also be enhanced (see, PATENT DOCUMENTS 1 and 2).

### CITATION LIST

### Patent Literature

### PATENT DOCUMENT 1

Japanese Patent Laid-Open Publication No. 2010-93194

### PATENT DOCUMENT 2

Japanese Patent Laid-Open Publication No. 2011-515872

### SUMMARY OF INVENTION

### Technical Problem

A texture element formed by anisotropic etching of silicon using an alkaline solution is a square pyramid having a face angle of about 55° to the substrate face. The tip of the texture element is easily broken when another object makes contact therewith, and there is a risk that the power generation efficiency is reduced because the recombination speed increases at a part where the tip of the texture element is broken. For example, the tip part of the texture element is sometimes broken due to contact with a conveyance apparatus while conveying a substrate on which texture elements are formed in the production process of a solar cell.

### Solution to Problem

The present invention is a solar cell comprising a plurality of texture elements adjacent to each other, wherein the plurality of texture elements comprise a first texture element having a curvature radius of a vertex thereof larger than a curvature radius of a valley thereof between adjacent texture elements.

### Advantageous Effect of Invention

According to the solar cell of the present invention, the reduction in power generation efficiency of solar cells can be suppressed.

### BRIEF DESCRIPTION OF DRAWINGS

FIG. 1 is a plain view illustrating a structure of a solar cell in an embodiment of the present invention.

FIG. 2 is a sectional view illustrating a structure of a solar cell in an embodiment of the present invention.

FIG. 3 is a view describing a curvature radius of a texture element in an embodiment of the present invention.

FIG. 4 is a scanning electron microscope observation photograph showing a structure of texture elements in an embodiment of the present invention.

FIG. 5 is a scanning electron microscope observation photograph showing a structure of texture elements in an embodiment of the present invention.

FIG. 6 is a sectional view describing a structure of texture elements in an embodiment of the present invention.

### DESCRIPTION OF EMBODIMENT

Hereinafter, an embodiment of the present invention will be described in detail; however, the present invention is not limited to the embodiment. Moreover, the drawings which are referred to in the embodiment are schematically drawn, and the dimension ratios of components or the like drawn in the drawings are sometimes different from those in actual articles. Specific dimension ratios or the like should be determined in consideration of the following description.

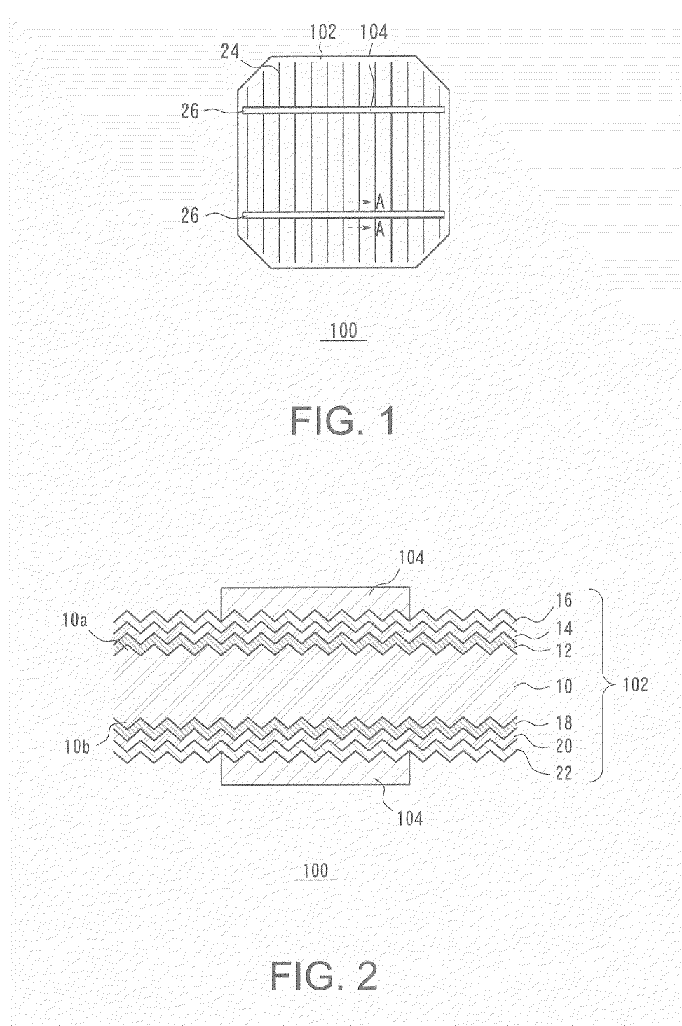

As illustrated in FIG. 1 and FIG. 2, a solar cell in the present embodiment is constituted by including a photoelectric conversion section 102 and a collector electrode 104.

FIG. 2 is a sectional view along the line A-A in FIG. 1. A “light-receiving face” designates a principal face on which light is mainly incident from outside of the photoelectric conversion section 102, and a “reverse face” designates a principal face opposite the light-receiving face. For example, more than 50% to 100% of the sunlight incident on the photoelectric conversion section 102 is incident from the light-receiving face side.

The photoelectric conversion section 102 has a semiconductor junction such as a pn or pin junction, or the like and is constituted of, for example, a crystalline semiconductor material such as monocrystalline silicon or polycrystalline silicon.

For example, the photoelectric conversion section 102 may be constituted by laminating an i-type amorphous silicon layer 12, a p-type amorphous silicon layer 14, and a transparent conductive layer 16 on the light-receiving face side of an n-type crystalline silicon substrate 10 and laminating an i-type amorphous silicon layer 18, an n-type amorphous silicon layer 20, and a conductive layer 22 on the reverse face side. The solar cell including such a constitution is called a heterojunction type solar cell and has a conversion efficiency that has been dramatically enhanced by interposing an intrinsic (i-type) amorphous silicon layer in the pn junction formed from the crystalline silicon and the p-type amorphous silicon layer. In addition, the conductive layer 22 on the reverse face side may be transparent or may not be transparent. Moreover, the photoelectric conversion section 102 is not limited to silicon and may be any material, so long as the material is a semiconductor material.

Texture elements 10a and 10b are preferably formed on both faces of the substrate 10 before laminating the respective layers. The texture elements 10a and 10b form uneven surface structures by which the surface reflection is suppressed to increase the amount of light absorption at the photoelectric conversion section 102.

For example, the texture elements 10a and 10b may be formed by performing anisotropic etching of a (100) plane of the substrate 10 using an aqueous alkaline solution such as a sodium hydroxide (NaOH) aqueous solution, a potassium hydroxide (KOH) aqueous solution, or tetramethylammonium hydroxide (TMAH). The substrate 10 having a (100) plane is anisotropically etched along a (111) plane when immersed in the alkaline solution, and a large number of convex parts each having a substantially square pyramid shape are formed on the surface of the substrate 10. For example, the concentration of the aqueous alkaline solution contained in an etchant is favorably 1.0 weight % to 7.5 weight %.

The shape and size of the texture elements 10a and 10b may be adjusted by varying the composition ratio and concentration of a solution used for etching, the time for conducting etching, and the temperature condition at the time of etching.

The i-type amorphous silicon layer 12, the p-type amorphous silicon layer 14, the i-type amorphous silicon layer 18, and the n-type amorphous silicon layer 20 may be formed by PECVD (Plasma Enhanced Chemical Vapor Deposition), Cat-CVD (Catalytic Chemical Vapor Deposition), a sputtering method, or the like. With respect to PECVD, any of an RF Plasma CVD method, a high frequency VHF Plasma CVD method, and a Micro Wave Plasma CVD method may be used.

For example, a raw material gas obtained by diluting silane (SiH₄) with hydrogen (H₂) is used for film-forming of the i-type amorphous silicon layers 12 and 18 by CVD. In the case of the p-type amorphous silicon layer 14, a raw material gas obtained by adding diborane (B₂H₆) to silane and diluting the resultant mixture with hydrogen (H₂) may be used. In the case of the n-type amorphous silicon layer 20, a raw material gas obtained by adding phosphine (PH₃) to silane and diluting the resultant mixture with hydrogen (H₂) may be used.

For example, the i-type amorphous silicon layer 12 having a thickness of about 5 nm is formed on the light-receiving face side of the substrate 10, and further the p-type amorphous silicon layer 14 having a thickness of about 5 nm is formed. Moreover, the i-type amorphous silicon layer 18 having a thickness of about 5 nm is formed on the reverse face side of the substrate 10, and further the n-type amorphous silicon layer 20 having a thickness of about 20 nm is formed. In addition, since the thickness of each layer is sufficiently thin, the shape of each layer reflects the shape of the texture elements 10a and 10b of the substrate 10. Specifically, the i-type amorphous silicon layer 12 and the p-type amorphous silicon layer 14 reflect the shape of the texture elements 10a of the substrate 10. The i-type amorphous silicon layer 18 and the n-type amorphous silicon layer 20 reflect the shape of the texture elements 10b of the substrate 10.

The transparent conductive layer 16 is constituted by containing at least one metal oxide such as indium oxide, zinc oxide, tin oxide, or titanium oxide. The metal oxide may be doped with a dopant such as tin, zinc, tungsten, antimony, titanium, cerium, or gallium. The constitution of the conductive layer 22 may be the same as or different from that of the transparent conductive layer 16. A metal film constituted from a material having a high reflectance such as Ag, Cu, Al, Sn, or Ni or a metal film constituted from an alloy thereof may be used as the conductive layer 22. Moreover, the conductive layer 22 may have a laminated structure of a transparent conductive film and a metal film. Thereby, the light incident from the light-receiving face reflects at the metal film and the power generation efficiency may be enhanced. The transparent conductive layer 16 and the conductive layer 22 may be formed by a film-forming method such as a vapor deposition method, a CVD method, or a sputtering method.

The collector electrode 104 for taking out the generated power to the outside is provided on the light-receiving face and the reverse face of the photoelectric conversion section 102. The collector electrode 104 includes a finger 24. The finger 24 is an electrode for collecting carriers produced in the photoelectric conversion section 102. The fingers 24 are formed, for example, in a wire shape having a width of about 100 μm and are positioned at intervals of 2 mm, in order to collect the carriers from the photoelectric conversion section 102 as evenly as possible. The collector electrode 104 may further be provided with a bus bar 26 for connecting the fingers 24 thereto. The bus bar 26 is an electrode for collecting a current of carriers collected by a plurality of fingers 24. The bus bar 26 is formed, for example, in a wire shape having a width of 1 mm. The bus bar 26 is positioned so as to cross the fingers 24 along the direction in which a connection member for connecting solar cells 100 to form a solar cell module is positioned. The number and area of the fingers 24 and bus bars 26 are appropriately set in consideration of the area and resistance of the solar cell 100. In addition, the collector electrode 104 may have the constitution in which the bus bar 26 is not provided.

In addition, the installation area of the collector electrode 104 provided on the light-receiving face side of the solar cell 100 is favorably made smaller than the installation area of the collector electrode 104 provided on the reverse face side. That is to say, the loss caused by the light being blocked off may be reduced by making the area in which the incident light is blocked off as small as possible on the light-receiving face side of the solar cell 100. On the other hand, since it is not necessary to take the incident light into consideration on the reverse face side, a collector electrode may be provided in place of the finger 24 and the bus bar 26 so as to cover the whole reverse face of the solar cell 100.

The collector electrode 104 may be formed using a conductive paste. The conductive paste may be a conductive paste containing a conductive filler, a binder, and an additive such as a solvent.

The conductive filler is mixed into the collector electrode for the purpose of realizing the electrical conductivity of the collector electrode. As the conductive filler, a metal particle such as, for example, silver (Ag), copper (Cu), or nickel (Ni); carbon; or a conductive particulate such as a mixture thereof is used. Among the conductive fillers, the silver particle is more preferably used. In the silver particle to serve as a filler, silver particles each having different sizes may be mixed or silver particle having uneven shapes provided on the surfaces thereof may be mixed. The binder is favorably a thermosetting resin. For example, polyester-based resins and so on are applied as the binder. Moreover, the conductive paste contains, as necessary, a curing agent that works well for the binder. A rheology-adjusting agent, a plasticizer, a dispersant, a defoaming agent, or the like may be contained as an additive in addition to the solvent.

The conductive paste may be applied on the light-receiving face and the reverse face in a predetermined pattern by a screen printing method. The screen printing method may be off-contact printing or on-contact printing. The collector electrode 104 is formed by applying the conductive paste on the light-receiving face and the reverse face of the photoelectric conversion section 102 in a predetermined pattern and performing heat curing treatment. The heat curing treatment may be performed at a lower temperature before the final heat curing treatment is performed.

In the present embodiment, the texture elements 10a and 10b are formed so as to include a texture element having a curvature radius of the vertex thereof, the curvature radius being larger than the curvature radius of the valley thereof between adjacent texture elements. When an etchant is in a high temperature state (for example, 85° C.), the etchant largely exhibits characteristics of anisotropic etching, and when the etchant is in a low temperature state (for example, 40° C.), the etchant largely exhibits characteristics of isotropic etching. For example, etching is performed on the substrate 10 with the etchant in a high temperature state (for example, 85° C.), texture elements 10a and 10b formed on the substrate 10 assume the shape of a substantially square pyramid whose vertexes and valleys are sharp. Thereafter, when additional etching to the substrate 10 is performed while making the etchant in a low temperature state (for example, 40° C.), the etching proceeds more at the vertexes of the texture elements 10a and 10b that have been formed on the substrate 10 than at the valleys, and therefore the curvature radius of the vertexes may be made larger than the curvature radius of the valleys between adjacent texture elements.

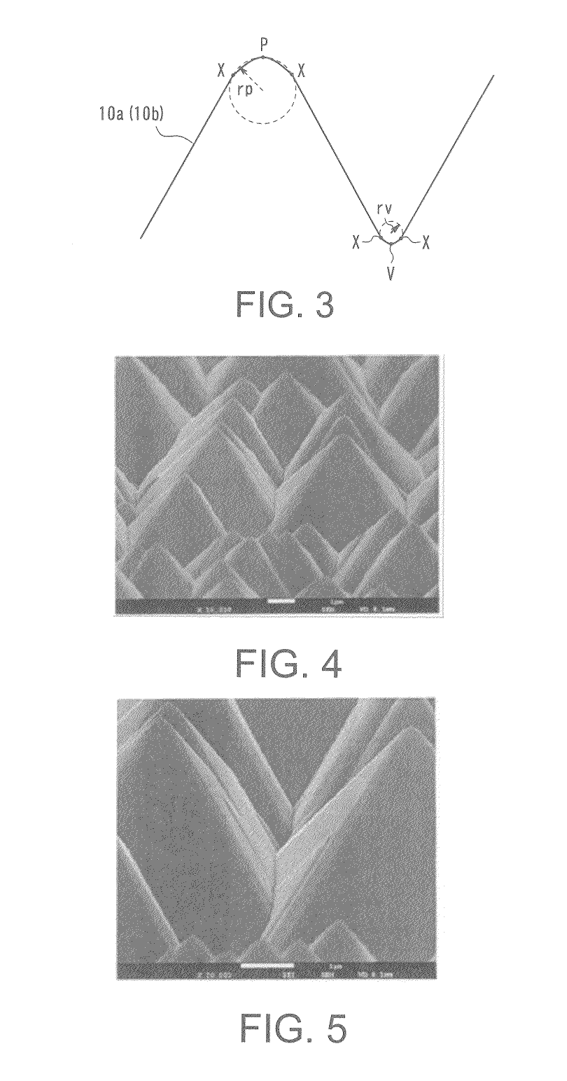

FIG. 3 illustrates a schematic diagram of a cross section of the texture element in which the curvature radius rp of a vertex P thereof is larger than the curvature radius rv of a valley V thereof between adjacent texture elements. The number of texture elements having a curvature radius rp of the vertex P larger than the curvature radius rv of the valley V is favorably made 50% or more of the whole number of vertexes of the texture elements 10a and 10b.

In addition, the curvature radius rp of the vertex P of the texture element 10a or 10b means, as illustrated in FIG. 3, the radius of an arc that includes points X where the slope of an inclined plane of the square pyramid constituting the texture element changes and the vertex P. Moreover, the curvature radius of the valley V of the texture element 10a or 10b means, as illustrated in FIG. 3, a radius of an arc that includes points X where the slope of an inclined plane of the square pyramid constituting the texture element changes and the vallV.

FIG. 4 and FIG. 5 are observation photographs of the texture elements 10a taken with a scanning electron microscope (SEM). FIG. 4 is an observation photograph showing a wide range of the substrate 10 where the texture elements 10a are formed, and FIG. 5 is an observation photograph showing an enlarged range thereof. In addition, the texture elements 10b having a shape similar to the shape of the texture elements 10a formed on the light-receiving face side may be formed also on the reverse face side of the substrate 10.

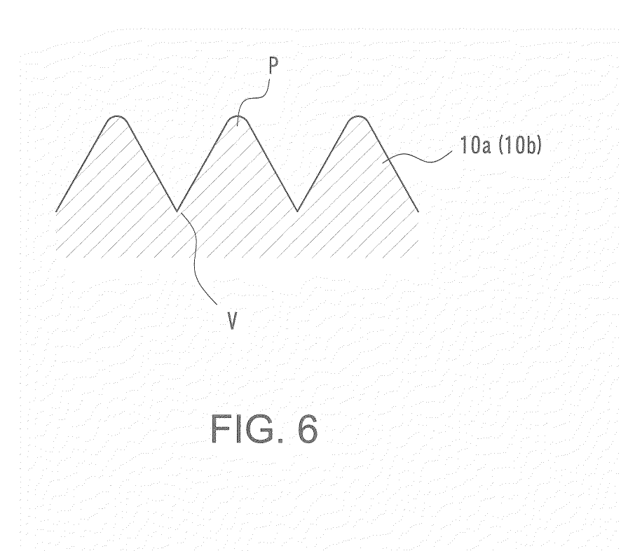

FIG. 6 illustrates a schematic diagram of a cross section of typical texture elements 10a seen in SEM observation photographs. As illustrated also in FIG. 5, the valley V of the texture element 10a is formed from lines made by a plurality of inclined planes of texture elements 10a overlapping with each other, the texture elements 10a each having a square pyramid shape. On the other hand, in a large number of texture elements 10a, the vertex P has a rounder shape than the valley V. That is to say, in at least a half of the texture elements 10a, the curvature radius of the vertex P is larger than the curvature radius of the valley V in the present embodiment.

The magnitude relation between the curvature radius of the vertex P and the curvature radius of the valley V of the texture elements 10a and 10b may be measured by a cross section observation photograph with an SEM. Specifically, the magnitude relation is measured by comparing the curvature radii of the vertex P and the valley V adjacent to each other of the texture elements 10a and 10b in the cross section observation photograph with an SEM measured at about 1000 magnifications.

As described above, by making the curvature radius of the vertex P of the texture elements 10a and 10b larger than the curvature radius of the valley V, the pressure has difficulty concentrating on the tip due to the large curvature radius even though another object makes contact with the vertex P of the texture elements 10a and 10b. Thereby, the occurrence of breakage at the tip of the texture elements 10a and 10b can be suppressed, and the recombination of carriers caused by the breakage can also be suppressed. Moreover, the large curvature radius of the vertex P can suppress the reflection of light incident on the solar cell at the vertex of the texture element and the characteristics of the solar cell can be enhanced.

In addition, the scope of the application of the present invention is not limited to the solar cell in the present embodiment and may include a solar cell having a texture element on the light-receiving face or the reverse face. For example, the present invention may be applied to crystalline or thin film solar cells.

1. A solar cell comprising a plurality of texture elements adjacent to each other,
wherein the plurality of texture elements comprise a first texture element having a curvature radius of a vertex thereof larger than a curvature radius of a valley thereof between adjacent texture elements.

2. The solar cell according to claim 1, wherein the first texture element bends so that a slope thereof decreases from the valley toward the vertex.

3. The solar cell according to claim 1, wherein the number of vertexes of the first texture elements is 50% or more of the total number of vertexes of the plurality of texture elements.

4. The solar cell according to claim 1, comprising:
a semiconductor substrate comprising a texture element;
an amorphous silicon layer formed on a surface of the semiconductor substrate; and
a transparent conductive layer formed on the amorphous silicon layer.
